(19) United States
(12) Patent Application Publication
(10) Pub. No.: US 2010/0149823 A1
(43) Pub. Date: Jun. 17, 2010

(54) LAMP UNIT, CIRCUIT BOARD, AND METHOD OF MANUFATURING CIRCUIT BOARD

(76) Inventor: Akihiko HAPPOYA, Kamakura-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/630,014

(22) Filed: Dec. 3, 2009

(30) Foreign Application Priority Data
Dec. 12, 2008 (JP) 2008-317573

(51) Int. Cl. F21V 29/00; H05K 1/09; B32B 38/00; H01B 13/00

(52) U.S. Cl. 362/373; 174/252; 156/278; 156/47

(57) ABSTRACT

A lamp unit includes a housing with high thermal conductivity, a circuit board fixed to the housing, and including an insulating layer, first copper material layer arranged to be superimposed on one surface side of the insulating layer, and forming a thermal conduction part, and second copper material layer arranged to be superimposed on the other surface side of the insulating layer, a trace part to be connected to an optical semiconductor element being formed in the second copper material layer, and the optical semiconductor element being mounted on the circuit board, and an opening part which is provided in the insulating layer, through which the first copper material layer is exposed toward the other surface side, and in which the optical semiconductor element is arranged with an undersurface thereof bonded to the first copper material layer.

### CROSS-REFERENCE TO RELATED APPLICATIONS

This application is based upon and claims the benefit of priority from prior Japanese Patent Application No. 2008-317573, filed Dec. 12, 2008, the entire contents of which are incorporated herein by reference.

### BACKGROUND OF THE INVENTION

1. Field of the Invention

The present invention relates to a lamp unit using a high-intensity LED, circuit board, and method of manufacturing the circuit board, and more particularly, to a technique enabling low cost, excellent thermal release, and exceptionally long life.

2. Description of the Related Art

LEDs (optical semiconductor elements) are widely employed in annunciator boards, traffic signals, and the like and, particularly, high-intensity LEDs are spread out over headlights, backlights, general lighting, and the like. The luminous efficiency of LEDs has improved year by year and the scope of use of LEDs is increasing. It should be noted that the LED is mounted on a circuit board to be used.

However, there is a problem that LED lighting is remarkably high in manufacturing cost as compared with the fluorescent lamp. Further, there is a problem that it is difficult to devise a countermeasure against heat in the LED lighting. That is, under the current circumstances, the energy conversion efficiency of the LED is about 20%, and the remaining about 80% becomes heat. For this reason, when the heat radiation of the LED element is not properly carried out, the LED element, peripheral fluorescent body, and reflection member become high in temperature, and degradation progresses to shorten the life. Further, the LED element exhibits a characteristic in which the lower the temperature, the higher the luminous efficiency is, and the higher the temperature, the lower the luminous efficiency is. Because of these circumstances, the countermeasure for the LED against heat is an important technical problem.

As the countermeasure for the LED against heat, a structure is known in which an LED is mounted on a printed circuit board including a metallic base using mainly aluminum by die bonding or wire bonding, and heat of the LED is conducted to the printed circuit board to thereby radiate the heat. Further, a structure is known in which an LED package is mounted on a printed circuit board with a metallic base, and heat of the LED is conducted to the printed circuit board to thereby radiate the heat.

Examples of the circuit board used to radiate heat include a circuit board using alumina or aluminum nitride as a base, circuit board using metals such as aluminum, copper, and iron as a base, and formed into a three-layer structure including an insulating layer, and copper traces, circuit board in which a metallic post (via hole) is arranged between the metallic base and copper traces to thereby form a path with high thermal conductivity (see for example, Jpn. Pat. Appln. KOKAI Publication No. 2005-167086), circuit board in which copper traces are arranged on one surface of a simple insulating layer, circuit board using phenolic paper, a composite material, epoxy-glass, and the like as an insulating layer, double-sided circuit board in which through holes are formed in an insulating layer of epoxy-glass or a composite material, and the like.

In the circuit boards for LED lighting, there has been the following problem. That is, in these circuit boards, when high heat radiation performance is required, the manufacturing cost tends to increase, and hence there is a problem that the manufacturing cost and heat radiation performance are not compatible with each other.

For example, as for the above-mentioned circuit board with the three-layer structure, first, an insulating layer is formed on the base metal of aluminum, copper, iron or the like. Formation of the insulating layer is carried out by sticking of a resin sheet, screen printing of resin or the like. Then, copper foil is laminated. After that, pattern formation is carried out, a solder resist layer is formed, and surface treatment is carried out in accordance with the mounting system. As the metallic base plate, a rolled metallic plate of a thickness of about 1 to 2 mm is used. As described above, the manufacturing process is complicated, and hence the manufacturing cost is increased.

On the other hand, when the thermal conduction is considered, there is an insulating layer between the base metal and copper traces, the thermal conductivity of the insulating layer is 0.2 to 0.4 W/mK when the material thereof is a general epoxy resin, and 1 to several W/mK even when the material contains inorganic filler, the thermal conductivity is lower than that of a metal of several tens to hundreds of W/mK, and hence the thermal resistance becomes comparatively high.

### BRIEF SUMMARY OF THE INVENTION

Thus, an object of the present invention is to provide a lamp unit, circuit board, and method of manufacturing the circuit board capable of preventing an optical semiconductor element and peripheral components from being degraded at low cost by efficiently conducting heat generated from the optical semiconductor element to the outside.

In order to solve the problem described previously and achieve the object, a lamp unit, circuit board, and method of manufacturing the circuit board are configured as follows.

According to an aspect of the invention, there is provided a lamp unit according to the present invention comprises a housing with high thermal conductivity; a circuit board fixed to the housing, and including an insulating layer, first copper material layer arranged to be superimposed on one surface side of the insulating layer, and forming a thermal conduction part, and second copper material layer arranged to be superimposed on the other surface side of the insulating layer, a trace part to be connected to an optical semiconductor element being formed in the second copper material layer, and the optical semiconductor element being mounted on the circuit board; and an opening part which is provided in the insulating layer, through which the first copper material layer is exposed toward the other surface side, and in which the optical semiconductor element is arranged with an undersurface thereof bonded to the first copper material layer.

According to another aspect of the invention, there is provided a circuit board configured to mount an optical semiconductor element according to the present invention comprises an insulating layer; a first copper material layer arranged to be superimposed on one surface side of the insulating layer, and forming a thermal conduction part; a second copper material layer arranged to be superimposed on the other surface side of the insulating layer, a trace part to be connected to the optical semiconductor element being formed therein; and an opening part which is provided in the insulating layer, through which the first copper material layer is exposed toward the other surface side, and in which the optical semiconductor element is arranged with an undersurface thereof bonded to the first copper material layer.

According to another aspect of the invention, there is provided a method of manufacturing a circuit board configured to mount an optical semiconductor element according to the present invention comprises the steps of: forming a first copper material layer on one surface of an insulating layer; forming a second copper material layer on the other surface of the insulating layer; forming an opening part in the insulating layer by removing a part of the insulating layer in such a manner that the first copper material layer is exposed from the other surface side; bonding an undersurface of the optical semiconductor element to the first copper material layer in the opening part; and joining an electrode of the optical semiconductor element to the second copper material layer.

According to another aspect of the invention, there is provided a method of manufacturing a circuit board configured to mount an optical semiconductor element according to the present invention comprises the steps of: sending each of first electrolytic copper foil, an insulator film, and second electrolytic copper foil from a roll of the first electrolytic copper foil, roll of the insulator film, and roll of the second electrolytic copper foil; and pressing and laminating the first electrolytic copper foil, insulator film, and second electrolytic copper foil.

According to the present invention, it becomes possible to prevent the optical semiconductor element and peripheral components from being degraded at low cost by efficiently conducting heat generated from the optical semiconductor element to the outside.

### BRIEF DESCRIPTION OF THE SEVERAL VIEWS OF THE DRAWING

FIG. 1 is a side view showing a LED lighting device according to a first embodiment of the present invention with the device partially cut away.

FIG. 2 is a cross-sectional view showing a circuit board incorporated in the LED lighting device.

FIG. 3 is a cross-sectional view showing a main part of the circuit board.

FIG. 4 is an explanatory view showing a manufacturing process of electrolytic copper foil used as a material for the circuit board.

FIG. 5 is an explanatory view showing a manufacturing process of an insulating layer used as a material for the circuit board.

FIG. 6 is an explanatory view showing a manufacturing process of the circuit board.

FIG. 7 is a cross-sectional view showing the manufacturing process of the circuit board.

FIG. 8 is a cross-sectional view showing the manufacturing process of the circuit board.

FIG. 9 is a cross-sectional view showing the manufacturing process of the circuit board.

FIG. 10 is a cross-sectional view showing the manufacturing process of the circuit board.

FIG. 11 is a cross-sectional view showing the manufacturing process of the circuit board.

FIG. 12 is a cross-sectional view showing a circuit board according to a second embodiment of the present invention.

### DETAILED DESCRIPTION OF THE INVENTION

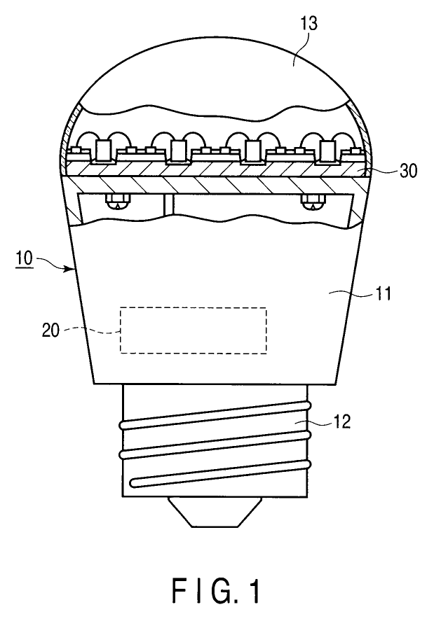

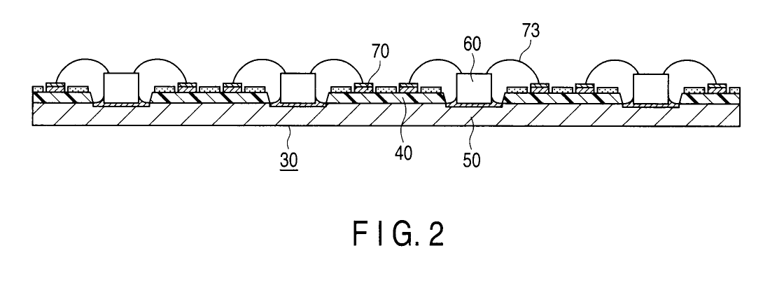

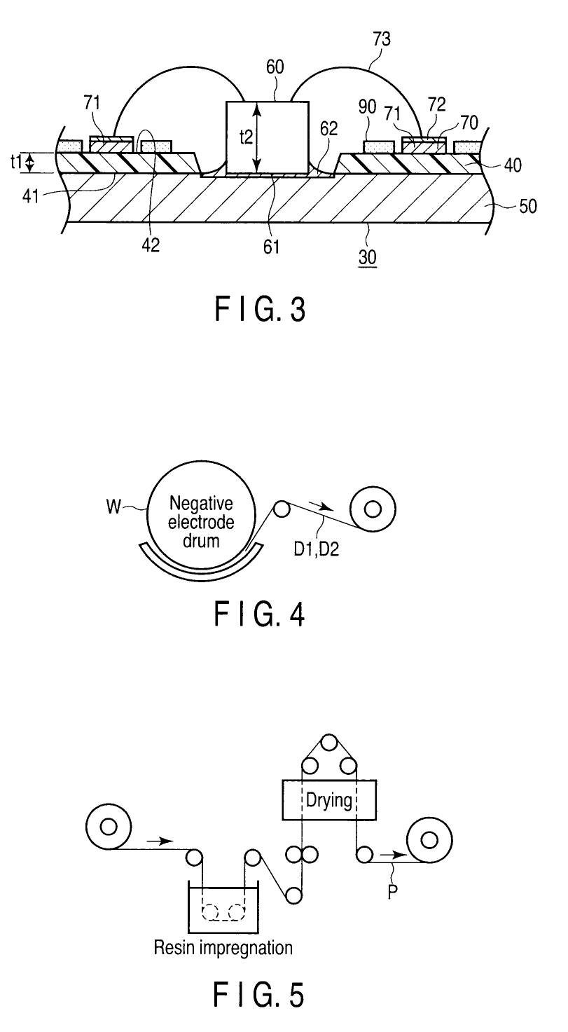

FIG. 1 is a side view showing an LED lighting device (lamp unit) 10 according to a first embodiment of the present invention with the device partially cut away. FIG. 2 is a cross-sectional view showing a circuit board 30 incorporated in the LED lighting device 10. FIG. 3 is a cross-sectional view showing a main part of the circuit board 30.

The LED lighting device 10 is provided with a housing 11 made of metal such as die-cast aluminum or the like. An electric circuit 20 such as an AC/DC converter or the like is contained in the housing 11. A circuit board 30 is fixed to an upper part of the housing 11 through screws, grease, thermally-conductive sheet, and the like in a state where high thermal conductivity is maintained. Further, a fixing part 12 configured to fix the device 10 to a socket (not shown) is provided at a lower part of the housing 11. It should be noted that a reference symbol 13 in FIG. 1 denotes a translucent cover.

The circuit board 30 is provided with an insulating layer 40, first copper material layer 50 superimposed on the undersurface 41 side of the insulating layer 40, and forming a thermal conduction part, second copper material layer 70 superimposed on the top surface 42 side of the insulating layer 40, a trace pattern 71 to be connected to LED elements 60 being formed in the second copper material layer 70. The trace pattern 71 is coated with a surface preparation agent 72 used to join the pattern 71 to metallic wires 73 to be described later. As the surface preparation agent 72, a gold-nickel treatment agent, silver treatment agent, silver-nickel treatment agent, and the like are used. The trace pattern 71 is connected to the electrodes of the LED elements 60 by using metallic wires of gold, aluminum, copper or the like.

Parts on the top surface 42 of the insulating layer 40 on which no trace pattern is formed are coated with a solder resist 90. Light reflectivity is imparted to the solder resist 90 in some cases, and a white solder resist with high reflectance is used in some cases.

It should be noted that a plurality of LED elements 60 are mounted on the circuit board 30. In general, in an LED lighting device, a plurality of LED elements 60 are mounted. Further, the LED element 60 is of a blue color type, and a p-type electrode and n-type electrode are provided on the same side.

An opening part 43 is provided in the insulating layer, the first copper material layer 50 is exposed toward the top surface 42 side, and the LED element 60 is arranged with an undersurface 61 thereof bonded to the first copper material layer 50 by means of a bonding agent 62. As the bonding agent 62, a solder material, silver paste material, resin-based material or the like with high thermal conductivity is used.

The sum total t1 of the thicknesses of the insulating layer 40 and second copper material layer 70 is set smaller than half the thickness t2 of the LED element 60. This is due to the following reason. That is, the LED element 60 exhibits a characteristic of emitting light not only from the top surface thereof but also from the side surface thereof. When the depth of the opening part 43 is too large, light emitted from the side surface of the LED element 60 is interrupted by the insulating layer 40 and second copper material layer 70. In order that the light emitted from the side surface may not be interrupted, it is necessary that the depth of the opening part 43 should be small to a certain degree, i.e., the sum total of the thicknesses of the insulating layer 40 and second copper material layer 70 should be small. The thickness t2 of the LED element 60 is generally 100 to 200 μm in order to cut (break) the LED element using a sapphire substrate as a base, a fillet height of a die bonding material is about 50 μm at the maximum, a part of the side surface of the LED element at which the fillet overlaps the LED element 60 does not contribute to light emission, and hence it is desirable that the sum total t1 of the thicknesses of the insulating layer 40 and second copper material layer 70 be 50 μm or less. Accordingly, it is desirable that the sum total t1 of the thicknesses of the insulating layer 40 and second copper material layer 70 be set smaller than half the thickness t2 of the LED element 60.

Next, the material, shape, and the like of each member will be described below. The insulating layer 40 is an insulator made of a resin such as an epoxy resin, phenolic resin, cyanate resin, BT resin, and the like, glass cloth impregnated with these resins, or these resins to which filler is added. The opening part 43 is formed by removing the corresponding part of the insulating layer by mechanical processing such as laser beam machining and milling.

The first copper material layer 50 is formed of electrolytic copper foil with a comparatively large thickness, and heat from the LED element 60 is directly conducted thereto. The first copper material layer 50 is formed by using the electrolytic copper foil, and hence the thickness thereof can be increased up to 420 μm at the maximum in manufacturing the foil. In consideration of the manufacturability and heat radiation performance, the thickness of 70 to 420 μm is employed. In the case of a metallic base board, in general, although a rolled metallic plate of a thickness of about 1 to 2 mm is used, cost reduction is enabled by using electrolytic copper foil.

The second copper material layer 70 is a trace pattern using electrolytic copper foil of a comparatively small thickness or a footprint for mounting, and is formed by etching electrolytic copper foil D2 with a thickness of 12, 18, or 35 μm as will be described later.

In the LED lighting device 10 configured as described above, power is supplied to the circuit board 30 through the electric circuit 20, and the LED elements 60 emit light. At this time, the heat generated from the LED elements 60 is directly conducted to the first copper material layer 50, and is further conducted to the housing 11. The housing 11 is a thermal conductor of a high degree, and furthermore the surface area thereof is large, and hence the heat is easily radiated.

Next, a method of manufacturing the above-mentioned circuit board 30 will be described below. As for the circuit board 30, a fundamental material Q is processed. Each of the first copper material layer 50 and second copper material layer 70 constituting the circuit board 30 is electrolytic copper foil as described above. Accordingly, the electrolytic copper foil is manufactured in the manner shown in FIG. 4. That is, a method in which copper is precipitated on a negative electrode drum W rotating in an acidic copper plating solution containing sulfuric acid and copper sulfate as main ingredients, then the precipitated copper is tore off from the drum W to continuously manufacture the copper foil D1 or D2 is employed. Then, the surface of the copper foil is subjected to surface treatment such as a roughness adjustment process, rust prevention process, and the like. As for the thickness of the copper foil, copper foil with a thickness of 12 to 420 μm is generally manufactured.

In this case, electrolytic copper foil D1 (with a thickness of 70 μm or greater) corresponding to the first copper material layer 50, and electrolytic copper foil D2 (with a thickness of 12 to 35 μm) corresponding to the second copper material layer 70 are formed.

On the other hand, as for the insulating layer 40, glass cloth is impregnated with a resin, and the resultant is dried, whereby a prepreg P (with a thickness of about 50 μm) of the B stage is manufactured. The term prepreg is abbreviation of pre-impregnation, and means prior impregnation. More specifically, the term prepreg means fiber impregnated with a thermosetting resin, and brought into a partially hardened state (i.e., B stage of resin). The resin is a thermosetting resin such as an epoxy resin, phenolic resin, cyanate resin, BT resin, and the like.

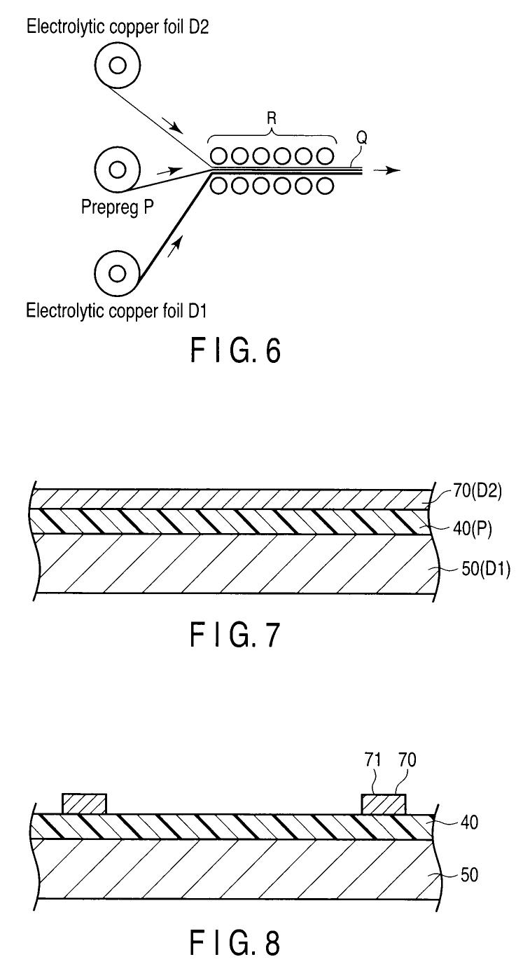

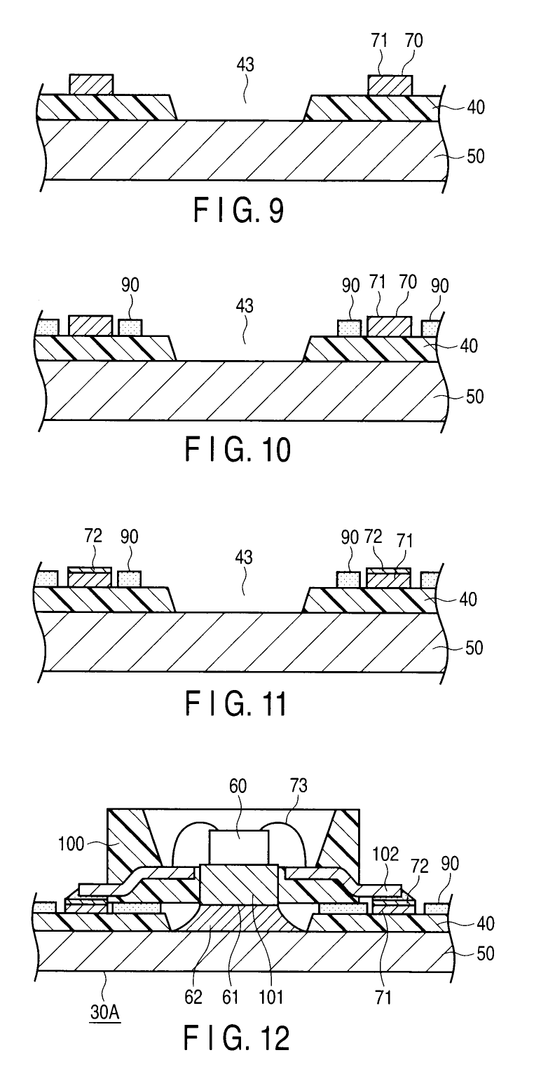

As shown in FIG. 6, electrolytic copper foil D1, electrolytic copper foil D2, and a prepreg P are prepared in rolls, conditions of heat, roll pressure, and feed speed are controlled on a roll laminator R, and the foil D1, foil D2, and prepreg P are continuously laminated. In the case of this configuration, the laminated product can be manufactured in a common width of the prepreg, i.e., 1.2 m. In the above-mentioned manner, it is possible to manufacture a fundamental material Q of a three-layer structure of electrolytic copper foil-insulating layer-electrolytic copper foil.

It should be noted that in place of using the roll laminator shown in FIG. 6, the electrolytic copper foil D1, electrolytic copper foil D2, and prepreg P in the roll form may be cut into a prescribed size, and these cut materials may be laminated in a press by controlling the heat and pressure. By such a method, it is possible to use a laminating press configured to manufacture a general copper-clad laminate, and manufacture the material in the sizes of 1.2 m×1 m, 1.2 m×2 m, 1.2 m×3 m, and the like.

Furthermore, a method in which resin coated copper foil formed by coating thin electrolytic copper foil with an insulating resin, and brought into the B-stage state is superimposed upon thick electrolytic copper foil may be used, and a resin film in the B-stage state, in which glass cloth is not contained in the prepreg may also be used.

The fundamental material Q formed in the manner described above is processed by etching the electrolytic copper foil D2 to form a trace pattern 71. As for the etching, it is general to carry out the process in the order of pretreatment, dry film sticking, exposure, development, etching, and dry film removal.

Then, formation of the opening part 43 is carried out by partially removing the insulating layer 40 by a method such as laser machining and the like. In place of the method described above, the insulating layer 40 may also be partially removed by a mechanical method such as Z-axis-controlled drilling and the like. After the removal machining, there are residual resin chips on the bottom surface of the opening part 43 in some cases, and hence cleaning is carried out by a desmear process using permanganic acid or soft etching process.

Then, a solder resist layer 90 is formed. As for the solder resist lay 90, there are two types, i.e., a photosensitive type, and thermosetting type, and they can be properly used in accordance with the accuracy and use. Next, surface treatment is carried out. It should be noted that the solder resist process and surface treatment process may be reversed in order according to circumstances.

As described above, according to the LED lighting device 10 associated with this embodiment, it is possible to transfer the heat generated from the LED element 60 directly to the first copper material layer 50 not by way of the insulating layer 40, and it is therefore possible to enhance the heat radiation performance.

Further, a rolled aluminum plate or copper plate is not used, and low-cost electrolytic copper foil is used. Accordingly, it is possible to carry out lamination in a large size of 1.2 m×1 m, 1.2 m×2 m, 1.2 m×3 m, and the like by using an equipment configured to manufacture, for example, a roll of 1.2 m width or a copper-clad laminate, and hence it is possible to efficiently carry out the manufacturing process, and obtain the cost reduction merit. Accordingly, it is possible to provide a LED mounting printed circuit board which enables cost reduction and high heat radiation performance to be compatible with each other.

FIG. 12 is a cross-sectional view showing a circuit board 30A according to a second embodiment of the present invention. In FIG. 12, the same parts as those in FIG. 3 are denoted by the same reference symbols as those in FIG. 3, and a detailed description of them are omitted.

In FIG. 12, a cap 100 made of a resin, and provided with a function of adjusting a refractive index is provided on an LED element 60. A metallic mounting part 101 used to mount the LED element thereon is provided inside the cap 100, and the mounting part 101 is joined to a first copper material layer 50. Further, a lead frame 101 is formed in the cap 100, and is connected to a trace pattern 71.

In this embodiment too, it is possible to transfer the heat generated from the LED element 60 to the first copper material layer 50 through the mounting part 101, and hence the same effect as the embodiment described previously can be obtained.

Furthermore, the cap 100 may be coated with a fluorescent substance converting a wavelength of light emitted from the LED element 60, or the fluorescent substance may be contained in a silicone resin.

It should be noted that although in each of the above-mentioned embodiments, an LED lighting device of the electric bulb type has been described, the present invention can also be applied to LED lighting of the downlight, mini krypton bulb, backlight, headlight, and the like.

It should be noted that the present invention is not limited to the above-mentioned embodiments as they are, and the constituent elements of the present invention can be modified and embodied in the implementation stage within the scope not deviating from the gist of the invention. Further, by appropriately combining a plurality of constituent elements disclosed in the above-mentioned embodiments, various inventions can be formed. For example, some constituent elements may be deleted from all the constituent elements shown in the embodiments. Furthermore, constituent elements of different embodiments may be appropriately combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A lamp unit comprising:
a housing with high thermal conductivity;
a circuit board fixed to the housing, and including an insulating layer, first copper material layer arranged to be superimposed on one surface side of the insulating layer, and forming a thermal conduction part, and second copper material layer arranged to be superimposed on the other surface side of the insulating layer, a trace part to be connected to an optical semiconductor element being formed in the second copper material layer, and the optical semiconductor element being mounted on the circuit board; and
an opening part which is provided in the insulating layer, through which the first copper material layer is exposed toward the other surface side, and in which the optical semiconductor element is arranged with an undersurface thereof bonded to the first copper material layer.

2. A circuit board configured to mount an optical semiconductor element comprising:
an insulating layer;
a first copper material layer arranged to be superimposed on one surface side of the insulating layer, and forming a thermal conduction part;
a second copper material layer arranged to be superimposed on the other surface side of the insulating layer, a trace part to be connected to the optical semiconductor element being formed therein; and
an opening part which is provided in the insulating layer, through which the first copper material layer is exposed toward the other surface side, and in which the optical semiconductor element is arranged with an undersurface thereof bonded to the first copper material layer.

3. The circuit board according to claim 2, wherein
a sum total of the thicknesses of the insulating layer and second copper material layer is smaller than half the thickness of the optical semiconductor element.

4. A method of manufacturing a circuit board configured to mount an optical semiconductor element comprising:
forming a first copper material layer on one surface of an insulating layer;
forming a second copper material layer on the other surface of the insulating layer;
forming an opening part in the insulating layer by removing a part of the insulating layer in such a manner that the first copper material layer is exposed from the other surface side;
bonding an undersurface of the optical semiconductor element to the first copper material layer in the opening part; and
joining an electrode of the optical semiconductor element to the second copper material layer.

5. A method of manufacturing a circuit board configured to mount an optical semiconductor element comprising:
sending each of first electrolytic copper foil, an insulator film, and second electrolytic copper foil from a roll of the first electrolytic copper foil, roll of the insulator film, and roll of the second electrolytic copper foil; and
pressing and laminating the first electrolytic copper foil, insulator film, and second electrolytic copper foil.
